(19) United States
(12) Patent Application Publication
(10) Pub. No.: US 2025/0341667 A1
(43) Pub. Date: Nov. 6, 2025

(54) LIQUID CRYSTAL MATERIAL, LAMINATE, OPTICAL MEMBER, DISPLAY DEVICE AND LAMINATE MANUFACTURING METHOD

(71) Applicant: SAMSUNG ELECTRONICS CO., LTD., Suwon-si (KR)

(72) Inventors: Tsuyoshi OHYAMA, Yokohama-shi (JP); Kazuo Udagawa, Yokohama-shi (JP); Yuichiro Goto, Yokohama-shi (JP); Yoshihiro Yokote, Yokohama-shi (JP)

(73) Assignee: SAMSUNG ELECTRONICS CO., LTD., Suwon-si (KR)

(21) Appl. No.: 19/269,760

(22) Filed: Jul. 15, 2025

Related U.S. Application Data
(63) Continuation of application No. PCT/IB2024/050474, filed on Jan. 18, 2024.

(30) Foreign Application Priority Data
Jan. 18, 2023 (JP) 2023-005893

(51) Int. Cl. G02B 5/30; C08F 222/20; C09K 19/38

(52) U.S. Cl. CPC G02B 5/3016; C08F 222/20; C09K 19/3852; C09K 2219/03

(57) ABSTRACT

Provided is a liquid crystal material configured to form a polymerizable liquid crystal compound, the liquid crystal material including a liquid crystal monomer, and an acrylamide monomer.

### CROSS-REFERENCE TO RELATED APPLICATIONS

This application is a bypass continuation of International Application No. PCT/IB2024/050474, filed on Jan. 18, 2024, which is based on and claims priority to Japanese Patent Application No. 2023-005893, filed on Jan. 18, 2023 filed in the Japan Intellectual Property Office, the disclosures of which are incorporated by reference herein in their entireties.

### BACKGROUND

### 1. Field

Embodiments of the present disclosure relate to a liquid crystal material, a laminate, an optical member, a display device, and a method for manufacturing a laminate.

### 2. Description of Related Art

An optical compensation film may have an optical foreign matter layer formed of a liquid crystal composition including a transparent support and a liquid crystal compound on the transparent support. On the optical anisotropic layer of the optical compensation film, a liquid crystal compound having a polymerizable group is homeotropically aligned.

### SUMMARY

One or more embodiments provide a liquid crystal material, a laminate, an optical member, a display device, and a method for manufacturing a laminate.

According to an aspect of one or more embodiments, there is provided a liquid crystal material configured to form a polymerizable liquid crystal compound, the liquid crystal material including a liquid crystal monomer, and an acrylamide monomer.

The liquid crystal material may further include a silane coupling agent.

The silane coupling agent may have an amino group.

The liquid crystal monomer may include at least one of a first liquid crystal monomer having a reaction group at both ends of a molecule and a second liquid crystal monomer having a reaction group at one end and a cyano group at the other end of a molecule.

A number of first liquid crystal monomer in the liquid crystal monomer may be greater than a number of the second liquid crystal monomer in the liquid crystal monomer.

A content of a material having an amino group may be greater than or equal to 1 part by mass and less than or equal to 30 parts by mass, based on a total of 100 parts by mass of the liquid crystal material.

According to another aspect of one or more embodiments, there is provided a laminate including a supporting layer, and a liquid crystal layer laminated on the supporting layer, the liquid crystal layer including a polymerizable liquid crystal compound that includes a liquid crystal monomer and an acrylamide monomer.

The liquid crystal layer may be formed by applying a liquid crystal material that include a liquid crystal monomer and an acrylamide monomer on the supporting layer and performing polymerization, and a water contact angle of the supporting layer may be greater than or equal to 30° and less than or equal to 60°.

The liquid crystal layer may be a positive C plate, the liquid crystal monomer being homeotropically aligned on the positive C plate, wherein the liquid crystal layer may satisfy −50 nm<Rth_C(550)<−150 nm, where Rth_C(λ) is a retardation for a wavelength λ (nm) of light in a thickness direction of the liquid crystal layer.

The supporting layer may satisfy nx2≥ny2>nz2, where refractive indexes in two directions in an in-plane direction of the supporting layer are nx2 and ny2, and a refractive index in a thickness direction of the supporting layer is nz2, and wherein the liquid crystal layer may be a positive C plate, the liquid crystal monomer being crosslinked in a homeotropically aligned state on the positive C plate and is directly laminated on the supporting layer.

The supporting layer may satisfy 10 nm<Re_A(550)<200 nm, where a retardation for a wavelength λ (nm) of light in an in-plane direction of the supporting layer is Re_A(λ).

The supporting layer may satisfy Re_A(450)<Re_A(550)<Re_A(650), where a retardation for a wavelength λ (nm) of light in an in-plane direction of the supporting layer is Re_A(λ).

The supporting layer may include at least one of diacetyl cellulose, triacetyl cellulose, cellulose acetate butylate, cellulose acetate propionate, cycloolefin, and polycarbonate, as a resin.

The supporting layer may include multiple types of resins having different wavelength dispersion properties.

The supporting layer may include the resin and particles.

### BRIEF DESCRIPTION OF DRAWINGS

Embodiments will be more clearly understood from the following detailed description taken in conjunction with the accompanying drawings in which:

FIG. 1 illustrates a retardation film according to an embodiment;

FIG. 2 illustrates an alignment state of a liquid crystal layer of the retardation film according to an embodiment;

FIG. 3 illustrates another form of the supporting layer according to an embodiment;

FIG. 4 illustrates an example of the method for manufacturing a retardation film of according to an embodiment;

FIG. 5 illustrates a liquid crystal display device to which the retardation film according to an embodiment is applied;

FIG. 6 illustrates an organic EL display device 2 to which the retardation film according to an embodiment is applied;

FIG. 7 illustrates graphs showing results of measuring luminance of a liquid crystal display device according to an embodiment; and

FIG. 8 illustrates graphs showing results of measuring luminance of a liquid crystal display device according to an embodiment.

### DETAILED DESCRIPTION

Hereinafter, embodiments for carrying out the present disclosure will be described in detail. In addition, the present disclosure is not limited to the following embodiments. In addition, the present disclosure may be carried out with various modifications within the scope of the gist. In addition, the drawings used in the following are intended to describe the embodiment of the present disclosure and do not represent an actual size.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

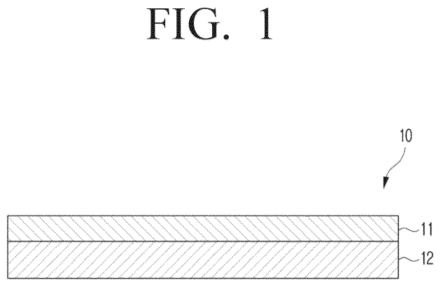

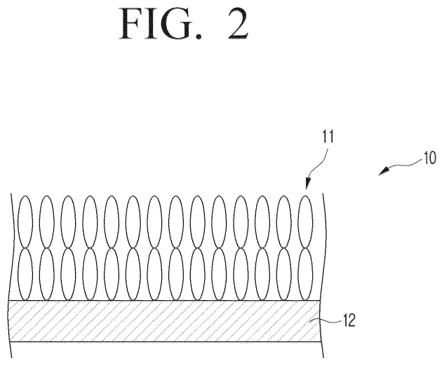

FIG. 1 is a drawing illustrating a retardation film 10 to which an embodiment is applied and shows an example of a cross-sectional structure of the retardation film 10. FIG. 2 is a drawing illustrating an alignment state of a liquid crystal layer 11 described later of the retardation film 10.

Though the details will be described later, the retardation film 10 of an embodiment is used by attaching the film to a display device such as a liquid crystal panel or an organic EL panel. By using the retardation film 10, viewing angle properties or suppression of external light reflection in the display device may be improved.

The retardation film 10 may be a laminate and includes a liquid crystal layer 11 formed of a polymerizable liquid crystal compound and a supporting layer 12 on which the liquid crystal layer 11 is laminated. In the retardation film 10 according to an embodiment, the liquid crystal layer 11 may be laminated directly on the supporting layer 12, without other layers such as an alignment layer.

A liquid crystal layer 11 is formed of a polymerizable liquid crystal compound including a liquid crystal monomer. The liquid crystal layer 11 of an embodiment may be a positive C plate, and as shown in FIG. 2, a liquid crystal monomer may be homeotropically aligned. In addition, on a liquid crystal layer 11, the alignment state of the liquid crystal monomer is fixed so that an alignment direction is vertical, by polymerizing a liquid crystal monomer.

The liquid crystal layer 11 of an embodiment includes a liquid crystal monomer and an acrylamide monomer.

The liquid crystal layer 11 includes a liquid crystal monomer having a reaction group in the molecule. A reaction group is a group which undergoes a polymerization reaction by irradiation (emission) with an active radiation such as visible light, ultraviolet rays, X-rays, electron rays, α-rays, β-rays, and γ-rays. A reaction group of the liquid crystal monomer is not particularly limited, but for example, may be a vinyl group, an acryl group, a methacryl group, an epoxy group, a styryl group, and the like. These reaction group may have a substituent.

In the case that the liquid crystal monomer has the reaction group in the molecule, the liquid crystal monomer is polymerized by the reaction group, thereby facilitating fixation of an alignment state of the liquid crystal monomer which is homeotropically aligned in the liquid crystal layer 11. Thus, changing the alignment state of the liquid crystal layer 11 over time may become more difficult, and reliability of the retardation film 10 is improved.

The liquid crystal layer 11 is a liquid crystal monomer having a reaction group in the molecule, and may include both a first liquid crystal monomer having a reaction group at both ends of the molecule and a second liquid crystal monomer having a reaction group at one end and a cyano group at the other end of the molecule. As the first liquid crystal monomer having the reaction group at both ends of the molecule, one type of liquid crystal monomer may be used alone, or multiple types of liquid crystal monomers may be used in combination. As the second liquid crystal monomer having the reaction group at one end and a cyano group at the other end of the molecule, one type of liquid crystal monomer may be used alone, or multiple types of liquid crystal monomers may be used in combination.

The first liquid crystal monomer having the reaction group at both ends of the molecule may be, for example, liquid crystal monomers of the following Chemical Formulae (1) to (9):

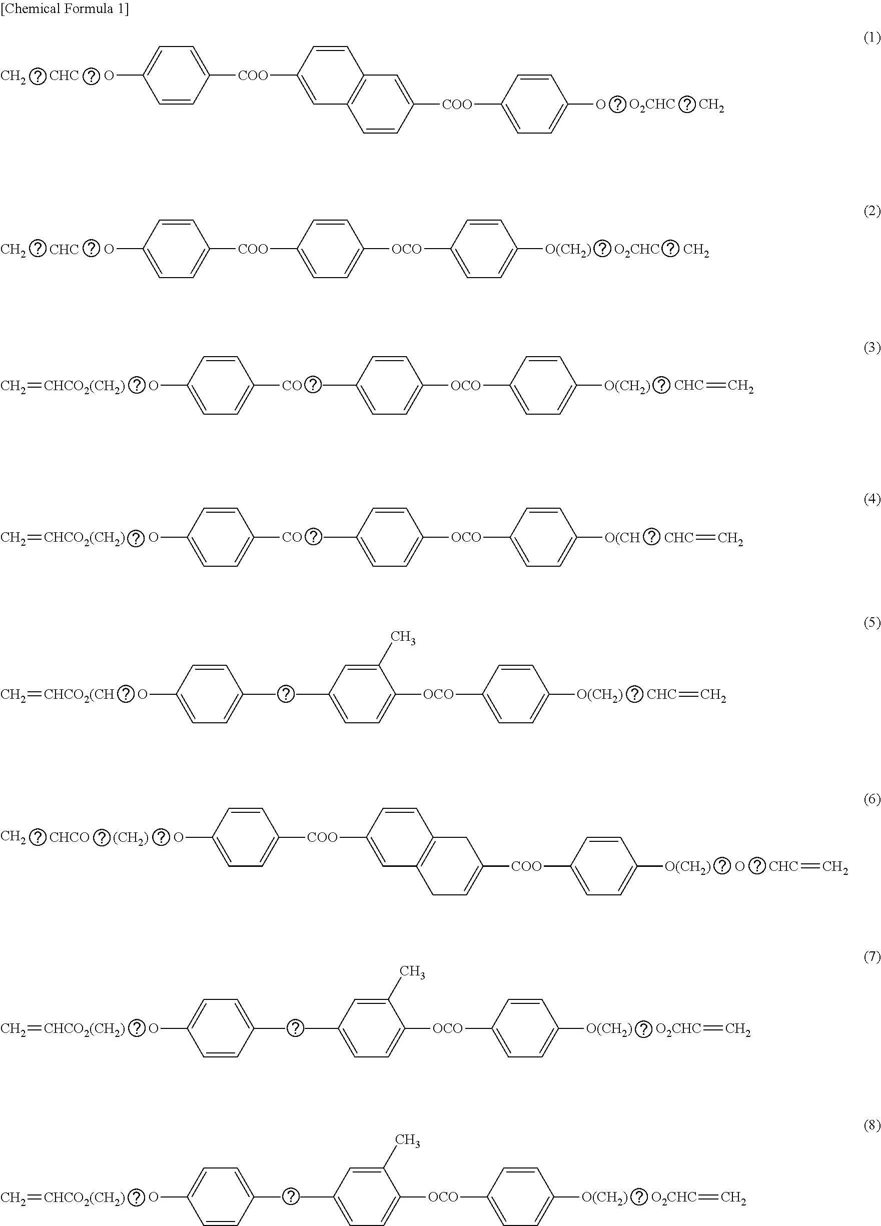

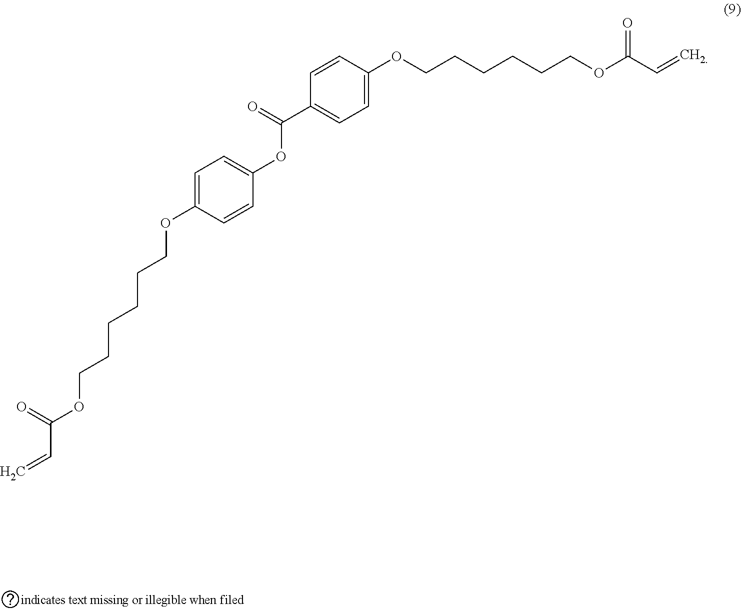 [SMILES: C=CC(=O)OCCCCCCOc1ccc(OC(=O)c2ccc(OCCCCCCOC(=O)C=C)cc2)cc1]

In addition, the second liquid crystal monomer having the reaction group at one end and a cyano group at the other end of the molecule may be, for example, liquid crystal monomers of the following Formulae (10) to (13):

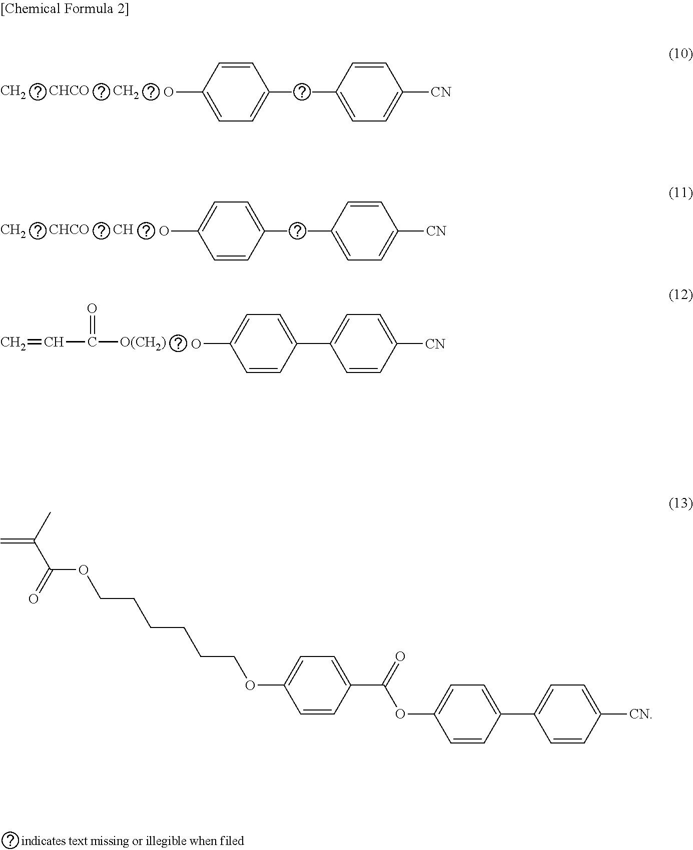

The liquid crystal layer 11 may include more first liquid crystal monomer having the reaction group at both ends of the molecule than the second liquid crystal monomer having the reaction group at one end and a cyano group at the other end of the molecule. In addition, the liquid crystal layer 11 including more first liquid crystal monomer than the second liquid crystal monomer means that the number of first liquid crystal monomer and structures derived from the first liquid crystal monomer is greater than the number of the second liquid crystal monomer and structures derived from the second liquid crystal monomer included in the liquid crystal layer 11.

The liquid crystal layer 11 includes more first liquid crystal monomer than the second liquid crystal monomer, thereby facilitating polymerization of liquid crystal monomers. Thus, fixation of the alignment state of the homeotropically aligned liquid crystal monomer may become easier, and the reliability of the retardation film 10 is further improved.

In addition, the liquid crystal layer 11 may further include other liquid crystal monomers having the reaction group at one end of the molecule, in addition to the first liquid crystal monomer and the second liquid crystal monomer described above.

As other liquid crystal monomers, for example, liquid crystal monomers of the following Formulae (14) to (18):

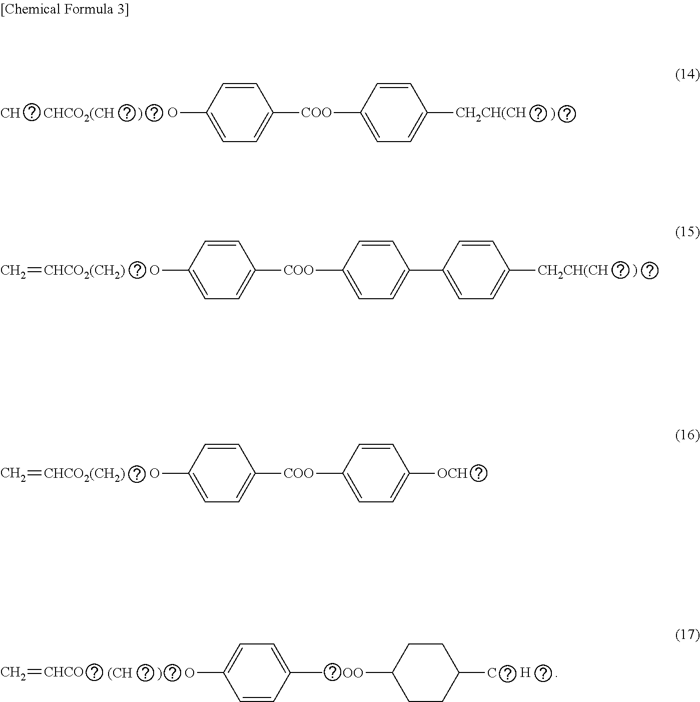

The liquid crystal monomer in the liquid crystal layer may include 50 parts by mass or more and 95 parts by mass or less, and may include 70 parts by mass or more and 90 parts by mass or less, based on a total of 100 parts by mass of the polymerizable liquid crystal compound forming the liquid crystal layer 11.

In the case that the content of the liquid crystal monomer is less than 50 parts by mass, the amount of the liquid crystal monomer included in the liquid crystal layer 11 may be decreased, and it may be difficult to polarize light incident on the liquid crystal layer 11.

In the case that the content of the liquid crystal monomer is more than 95 parts by mass, alignment of the liquid crystal material is degraded, and homeotropic alignment may become more difficult.

In addition, the liquid crystal layer 11 includes the acrylamide monomer represented by the following Formula (18):

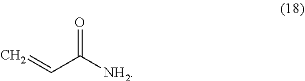

The liquid crystal layer 11 of an embodiment includes the acrylamide monomer, whereby the acrylamide monomer and the liquid crystal monomer are crosslinked, and the alignment state of the homeotropically aligned liquid crystal monomer may be easier to be fixed. Thus, as adhesiveness between the liquid crystal layer 11 and the supporting layer 12 is improved, changing the alignment state of the liquid crystal layer 11 over time may become more difficult, and the reliability of the retardation film 10 is improved.

In addition, the liquid crystal layer 11 includes the acrylamide monomer, thereby, for example, facilitating the homeotropic alignment of the liquid crystal monomer in the liquid crystal layer 11, even in the case of not preparing the alignment layer on the supporting layer 12. Thus, in the manufacture of the retardation film 10, a process of forming an alignment layer is not required, and the manufacture of the retardation film 10 may be more simplified.

The content of the acrylamide monomer in the liquid crystal layer 11 may be 1 part by mass or more and 30 parts by mass or less, and may be 5 parts by mass or more and 20 parts by mass or less, based on a total of 100 parts by mass of the polymerizable liquid crystal compound forming the liquid crystal layer 11.

In the case that the content of the acrylamide monomer is less than 1 part by mass, it may be difficult for the acrylamide monomer to be crosslinked with the liquid crystal monomer, and it may be easier for the alignment properties of the liquid crystal layer 11 on which the liquid crystal monomer is homeotropically aligned to change over time. Thus, the reliability of the retardation film is more easily deteriorated. In addition, adhesiveness between the liquid crystal layer 11 and the supporting layer 12 may be reduced.

In the case that the content of the acrylamide monomer is more than 30 parts by mass, the content of the liquid crystal monomer included in the liquid crystal layer 11 is relatively decreased, and thus, it may be difficult to polarize light incident on the liquid crystal layer 11.

In addition, the liquid crystal layer 11 may include a silane coupling agent, in addition to the liquid crystal monomer and the acrylamide monomer. The silane coupling agent is a compound containing silicon and a compound having a hydrolysis group which reacts with an inorganic material and an organic functional group which reacts with an organic material.

It may become easier for the liquid crystal monomer to be homeotropically aligned in the liquid crystal layer 11, by including the silane coupling agent in the liquid crystal layer 11.

The silane coupling agent may be, for example, an amino-based silane coupling agent having an amino group as an organic functional group, a silane coupling agent having a (meth)acryloyl group as an organic functional group, a mercapto-based silane coupling agent having a mercapto group as an organic functional group, an epoxy-based silane coupling agent having an epoxy group as an organic functional group, a sulfide-based silane coupling agent having sulfide as an organic functional group, and the like. Herein, the (meth)acryloyl group refers to an acryloyl group or a methacryloyl group. The silane coupling agent may be used alone or in combination of multiple types.

The liquid crystal layer 11 of an embodiment may use an amino-based silane coupling agent having an amino group as an organic functional group, among those silane coupling agents. The liquid crystal layer 11 includes the amino-based silane coupling agent, thereby facilitating the homeotropic alignment of the liquid crystal monomer in the liquid crystal layer 11, as compared with the case of using other silane coupling agents.

The amino-based silane coupling agent may be, for example, N-2(aminoethyl) 3-aminopropylmethyldimethoxysilane, N-2(aminoethyl) 3-aminopropyltrimethoxysilane, 3-aminopropyltriethoxysilane, 3-aminopropyltrimethoxysilane, 3-aminopropyltriethoxysilan, 3-triethoxysilyl-N-(1,3-dimethyl-butylidene) propylamine, and N-phenyl-3-aminopropyltrimethoxysilane.

The silane coupling agent having a (meth)acryloyl group may be, for example, 3-methacryloxypropylmethyldimethoxysilane, 3-methacryloxypropyltrimethoxysilane, 3-methacryloxypropylmethyldiethoxysilane, 3-methacryloxypropyltrimethoxysilane, and 3-acryloxypropyltrimethoxysilane.

The mercapto-based silane coupling agent may be, for example, 3-mercaptopropylmethyldimethoxysilane and 3-mercaptopropyltrimethoxysilane.

The epoxy-based silane coupling agent may be, for example, 3-glycidoxypropylmethyldiethoxysilane, 3-glycidoxypropyltriethoxysilane, and 2-(3,4-Epoxycyclohexyl)ethyltrimethoxysilane.

The sulfide-based silane coupling agent may be, for example, bis[3-(triethoxysilyl)propyl] tetrasulfide.

In the case that the liquid crystal layer 11 includes the silane coupling agent, the content of the silane coupling agent in the liquid crystal layer 11 may be 1 part by mass or more and 20 parts by mass or less, and may be 2 parts by mass or more and 10 parts by mass, based on a total of 100 parts by mass of the polymerizable liquid crystal compound forming the liquid crystal layer 11.

In addition, the liquid crystal layer 11 of an embodiment has the content of the material having an amino group of 1 part by mass or more and 35 parts by mass or less, and may have 5 parts by mass or more and 25 parts by mass or less, based on a total of 100 parts by mass of the polymerizable liquid crystal compound forming the liquid crystal layer 11.

Herein, the material having an amino group included in the liquid crystal layer 11 may be an acrylamide monomer, an amino-based silane coupling agent, and the like.

By setting the content of the material having an amino group included in the liquid crystal layer 11 to the above range, for example, even in the case that the contact angle of the supporting layer 12 to the liquid crystal material which serves as the basis of the liquid crystal layer 11 is relatively high, it may be easier for the liquid crystal monomer to be homeotropically aligned.

In addition, the liquid crystal layer 11 of an embodiment may further include other additives, if necessary, in addition to the liquid crystal monomer, the acrylamide monomer, and the silane coupling agent described above. Other additives included in the liquid crystal layer 11 may be, though not particularly limited, for example, a photopolymerization initiator, a leveling agent, and the like.

The photopolymerization initiator may be, for example, 2-methyl-[4-(methylthio)phenyl]-2-morpholino-1-propan, 1-[4-(2-hydroxyethoxy)-phenyl]-2-hydroxy-2-methylpropan, 2, 2′-dihydroxy-2, 2′-dimethyl-1,1′-[methylenebis(4,1-phenylene)]bis(propan-1-one), and the like. In addition, the photopolymerization initiator may be IRGACURE OXE04, IRGACURE OXE02, and IRGACURE OXE01, and the like.

The leveling agent may be a fluorine-based leveling agent, an acryl-based leveling agent, and a silicon-based leveling agent.

The fluorine-based leveling agent may be MEGAFAC R-08, R-30, R-90, F-410, F-411, F-114, F-510, F-551, RS-56, RS-72-K, RS-75, RS-76-E, RS-76-NS, RS-78, RS-90, DS-21, Surflon S-381, S-382, S-383, S393, SC-101, SC-105, KH-40, SA-100, and the like.

The acryl-based leveling agent may be BYK-350, BYK-352, BYK-353, BYK-354, BYK-355, BYK-356, BYK-358N, and the like.

The silicon-based leveling agent may be BYK-300, BYK-302, BYK-306, BYK-307, BYK-310, BYK-313, BYK-315N, BYK-320, BYK-322, BYK-323, BYK-325, BYK-330, KF-945, KF-6015, KF-6020, and the like.

The liquid crystal layer 11 has a thickness of 3 μm or less, or may be 2 μm or less. The liquid crystal layer 11 may be 0.3 μm or more, or may be 0.5 μm or more.

The liquid crystal layer 11 is a positive C plate, as described above and in the case that refractive indexes in two directions in an in-plane direction of the liquid crystal layer 11 are nx1 and ny1, and a refractive index in the thickness direction of the liquid crystal layer 11 is nz1, the liquid crystal layer satisfies nz1>nx1=ny1. Herein, nx1 refers to a refractive index in one direction in the plane of the liquid crystal layer 11, and ny1 refers to a refractive index in a direction orthogonal to one direction of nx1 in the plane of the liquid crystal layer 11. In addition, nz1 refers to a refractive index in the thickness direction of the liquid crystal layer 11. In addition, in the liquid crystal layer 11, the relationship of refractive index nx1=ny1 is not needed to be strictly established and may be almost the same.

In addition, in the case that the retardation for a wavelength (λ) of light in the thickness direction of the liquid crystal layer 11 is Rth_C(λ), the liquid crystal layer 11 may satisfy −50 nm<Rth_C(550)<−150 nm.

The thickness of the liquid crystal layer 11 is calculated (obtained) from the relationship between the refractive index of the liquid crystal layer 11 and the retardation Rth_C. Further, in the case that the thickness of the liquid crystal layer 11 is d, in order to realize the retardation Rth_C needed as the liquid crystal layer 11, the thickness d required for the liquid crystal layer 11 is calculated from the relationship of Rth_C=((nx1+ny1)/2−nz1)×d. In the case of using a common liquid crystal material, the thickness d of the liquid crystal layer 11 is 0.5 μm or more and 2 μm or less.

Next, the configuration of the supporting layer 12 will be described.

In the case that refractive indexes in the two directions in the in-plane direction of the supporting layer 12 are nx2 and ny2, and a refractive index in the thickness direction of the supporting layer 12 is nz2, the supporting layer 12 of an embodiment satisfies nx2≥ny2>nz2. Herein, nx2 refers to a refractive index in the slow axis of the supporting layer 12, ny2 refers to a refractive index in the fast axis which is orthogonal to the slow axis of the supporting layer 12, and nz2 refers to a refractive index in the thickness direction of the supporting layer 12.

In addition, the supporting layer 12 may be a positive A plate of which the refractive index satisfies nx2=ny2>nz2 or a negative B plate of which the refractive index satisfies nx2>ny2>nz2. In addition, the relationship of the refractive index nx2=ny2 in the case that the supporting layer 12 is the positive A plate does not need to be strictly established and may be almost the same.

In addition, in the supporting layer 12, in the case that the retardation for the wavelength (λ) of light in the in-plane direction of the supporting layer 12 is Re_A(λ), the wavelength dispersion properties of the retardation Re_A(λ) in the in-plane direction are reverse wavelength dispersion properties from flat dispersion. The reverse wavelength dispersion properties may indicate that the retardation value Re_A(λ) is increased as the light wavelength is increased. For example, in the supporting layer 12, Re_A(λ) in the in-plane direction satisfies Re_A(450)<Re_A(550)<Re_A(650).

In addition, in the supporting layer 12, the retardation Re_A(λ) in the in-plane direction satisfies Re_A(450)/Re_A(550)<0.9.

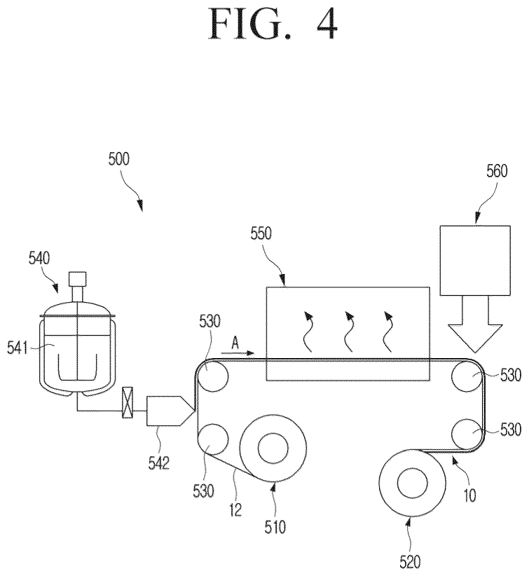

Since the wavelength dispersion properties of the retardation Re_A(λ) in the in-plane direction of the supporting layer 12 are reverse wavelength dispersion properties, in the case that the retardation film 10 of an embodiment is applied to a display device such as a liquid crystal display device 1 (see FIG. 4) described later, a light leakage phenomenon in the case of viewing the display device in an oblique angle may occur less. Thus, in the display device having the retardation film 10 of an embodiment, a contrast ratio in the case of being viewed in an oblique direction is improved.

In addition, in the case that a retardation for a wavelength (λ) of light in the in-plane direction of the supporting layer 12 is Re_A(λ), the supporting layer 12 may satisfy 10 nm<Re_A(550)<200 nm.

The supporting layer 12 may be formed by, for example, a resin-extended film. The supporting layer 12 includes at least one of cyclo-olefin polymer (COP), triacetyl cellulose (TAC), cellulose acetate propionate (CAP), diacetyl cellulose, acetyl cellulose, and polycarbonate. The supporting layer 12 may include these resins alone, but may include a plurality of resins having different wavelength dispersion properties of the retardation in the in-plane direction in the case that it is in the form of a film.

In addition, the supporting layer 12 preferably includes any one of triacetyl cellulose, cellulose acetate propionate, diacetyl cellulose, acetyl cellulose, and more preferably includes triacetyl cellulose and diacetyl cellulose, among these resins.

In the supporting layer 12, the wavelength dispersion properties of the retardation Re_A(λ) in the in-plane direction of the supporting layer 12 may be controlled to a predetermined state, by adjusting the content ratio of a plurality resins having different wavelength dispersion properties. For example, in the supporting layer 12, the wavelength dispersion properties of the retardation Re_A(λ) in the in-plane direction of the supporting layer 12 may be controlled to a predetermined state, by adjusting the content ratio of triacetyl cellulose and diacetyl cellulose.

The content ratio of triacetyl cellulose and diacetyl cellulose in the supporting layer 12 may be in a range of triacetyl cellulose:diacetyl cellulose=30:70 to 60:40, by weight ratio.

In addition, the supporting layer 12 may include an unreacted monomer which is a raw material of a resin, and the like, in addition to the resin. In addition, the supporting layer 12 may include other additives such as a dispersant, a defoaming agent, and a leveling agent.

In addition, the supporting layer 12 may have a water contact angle of the surface on which the liquid crystal layer 11 is laminated of 30° or more and 60° or less. In the case that the water contact angle of the supporting layer 12 is more than 60°, in the case of applying the liquid crystal material to the supporting layer to form the liquid crystal layer 11, it may be difficult for the liquid crystal monomer included in the liquid crystal layer 11 to be homeotropically aligned. In the case that the water contact angle of the supporting layer 12 is less than 30°, the homeotropic alignment of the liquid crystal monomer may not be affected, but a surface treatment for realizing the supporting layer 12 having a relatively small contact angle may be more easily complicated.

In addition, the supporting layer 12 may have a thickness of 100 μm or less, or 50 μm or less. The supporting layer 12 may have a thickness of 5 μm or more, or 10 μm or more.

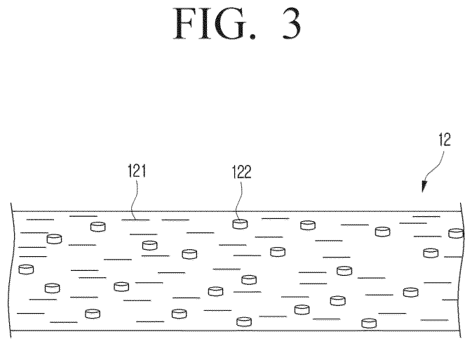

Herein, the supporting layer 12 is not limited to a film formed of the resin described above, and for example, may be formed of a film including particles in addition to the resin. Next, forms other than the supporting layer 12 will be described. FIG. 3 is a drawing illustrating other forms of the supporting layer 12, and a drawing showing an example of a cross section of the supporting layer 12.

The supporting layer 12 shown in FIG. 3 has a resin part 121 formed of a resin and particles 122. In addition, the supporting layer 12 may include an unreacted monomer which is a raw material of the resin forming the resin part 121 or other additives such as a dispersant, a defoaming agent, or a leveling agent, in addition to the resin part 121 and the particles 122, like the examples described above.

The resin forming the resin part 121 is the main component of the supporting layer 12. Therefore, the supporting layer 12 may be regarded as being particles 122 dispersed in the resin part 121. However, the particles 122 may not be dispersed in the entire resin part 121 and may be partially aggregated. In addition, partially aggregated particles 122 may be dispersed in the resin part 121.

The supporting layer 12 has the resin part 121 and the particles 122, thereby allowing the wavelength dispersion properties of the retardation Rth_A(λ) in the thickness direction of the supporting layer 12 to be controlled. In addition, in the supporting layer 12, the wavelength dispersion properties of the retardation Rth_A(λ) in the thickness direction of the supporting layer 12 may be controlled, by adjusting the mixed ratio between the resin part 121 and the particles 122, the refractive index of the particles 122, and the like.

In the supporting layer 12 of an embodiment, the wavelength dispersion properties in the retardation Re_A(λ) in the in-plane direction are different from those in the retardation Rth_A(λ) in the thickness direction. In addition, for example, in the case that the retardation Re_A(λ) in the in-plane direction of the supporting layer 12 is reverse wavelength dispersion properties, the retardation Rth_A(λ) in the thickness direction of the supporting layer 12 is forward wavelength dispersion properties which decrease as the wavelength increases or flat wavelength dispersion properties which rarely change as the wavelength increases.

In addition, it is preferred that in the supporting layer 12 of an embodiment, the retardation Re_A(λ) in the in-plane direction and the retardation Rth_A(λ) in the thickness direction satisfy Re_A(450)/Re_A(550)<Rth_A(450)/Rth_A(550).

The resin forming the resin part 121 may be at least one of cyclo-olefin polymer (COP), triacetyl cellulose (TAC), cellulose acetate propionate (CAP), diacetyl cellulose, acetyl cellulose, and polycarbonate, like the examples described above. For example, any one of triacetyl cellulose, cellulose acetate propionate, diacetyl cellulose, and acetyl cellulose may be used alone or in combination.

The particles 122 are fine particles and also, preferably nanoparticles. The particle diameter of the particles 122 is not particularly limited, but, for example, in a range of 1 nm or more and 400 nm or less.

In the case that refractive indexes in two directions in the in-plane direction of the supporting layer 12 are nx3 and ny3, and a refractive index in the thickness direction of the supporting layer is nz3, it is preferred that the particles 122 satisfy nx3>ny3>nz3. Herein, ny3 refers to a refractive index of the particles 122 in the slow axis direction of the supporting layer 12, ny3 refers to a refractive index of the particles 122 in the fast axis direction which is orthogonal to the slow axis of the supporting layer 12, and nz3 refers to a refractive index of the particles 122 in the thickness direction of the supporting layer 12.

In addition, in the case that a retardation for a wavelength λ (nm) of light in the thickness direction of the supporting layer 12 is Rth_P(λ), it is preferred that the particles 122 satisfy Rth_P(450)>Rth_P(550)>Rth_P(650).

As the particles 122, for example, smectite may be used. In addition, for example, minerals of a smectite family may be used other than smectite. For example, hectorite, montmorillonite, and bentonite may be used. In addition, kaolinite which is a mineral of a kaolinite family, antigorite, and mica which is a mineral of a mica family may be used.

Among them, in an embodiment, organic smectite obtained by artificial synthesis may be particularly preferably used as the particles 122. The organic smectite may be, for example, dimethyl stearyl ammonium hectorite. In addition, the organic smectite may be lithium silicate·sodium·magnesium·trioctylmethylammonium. In addition, the organic smectite may be lithium silicate·sodium·magnesium chloride polyoxyethylene coco-caprylate methyl ammonium.

A mixing ratio between the resin part 121 and the particles 122 in the supporting layer 122 may be in a range of resin:particle=95:5 to 70:30, by a weight ratio.

Within the mixing range, the wavelength dispersion properties of the retardation Rth_A(λ) in the thickness direction of the supporting layer 12 may be more easily controlled.

Next, a method for manufacturing a retardation film 10 will be described.

In the case of manufacturing a retardation film 10, first, a liquid crystal material which is a basis of a polymerizable liquid crystal compound forming a liquid crystal layer 11 is prepared.

The liquid crystal material includes the liquid crystal monomer and the acrylamide monomer described above. In addition, the liquid crystal material may include various additives described above, if necessary. The liquid crystal material may include a silane coupling agent, and a silane coupling agent having an amino group, as an additive.

In addition, in an embodiment, the content of the material having an amino group may be 1 part by mass or more and 30 parts by mass or less, or 5 parts by mass or more and 20 parts by mass or less, based on 100 parts by mass of the liquid crystal material. As described above, the material having an amino group may be an acrylamide monomer, an amino-based silane coupling agent, and the like.

By setting the content of the material having an amino group in the liquid crystal material to the range, for example, even in the case of using the supporting layer 12 having a high contact angle to the liquid crystal material, it is easy for the liquid crystal monomer to be homeotropically aligned.

The liquid crystal material is used after being dispersed in a solvent.

The solvent is not particularly limited as long as it may uniformly disperse the liquid crystal monomer and the acrylamide monomer included in the liquid crystal material. The solvent may be, for example, acetone, toluene, xylene, benzene, cyclohexane, hexane, methyl acetate, ethyl acetate, butyl acetate, isopropyl acetate, propyl acetate, methyl isobutyl ketone, methyl isobutyl ketone, propylene glycol methyl ether acetate, propylene glycol monomethylether, cyclohexanone, cyclopentanone, and the like.

Subsequently, the liquid crystal material is applied on the supporting layer 12.

FIG. 4 is a drawing illustrating an example of the method for manufacturing a retardation film 10 of an embodiment (see FIG. 1), and a drawing showing a coating device 500 used for the manufacture of the retardation film 10. FIG. 4 shows a state of applying the liquid crystal material which is a material of the liquid crystal layer 11, on a film-shaped supporting layer 12, using the coating device 500.

The coating device 500 has a supply part 510 which supplies a supporting layer 12 wound around in a roll shape while rewinding the supporting layer, a recovery part 520 which recovers a retardation film 10 obtained by forming a liquid crystal layer 11 on the supporting layer 12 while winding up the film. In addition, the coating device 500 has a plurality of conveyance rolls 530 which transports the supporting layer 12 in the direction of arrow A while simultaneously supporting the supporting layer 12 from the back side. In addition, the coating device 500 has an application part 540 which applies a liquid crystal material which is the material of the liquid crystal layer 11 on the surface of the supporting layer 12 which is transported by a transport roll 530. In addition, the coating device 500 has a heating part 550 which heats the liquid crystal material applied on the supporting layer 12. In addition, the coating device 500 has an irradiation part 560 which irradiates (emits) the liquid crystal material after passing through the heating part 550 with ultraviolet rays which is an example of active radiation.

In the coating device 500, the liquid crystal material is applied on the surface of the supporting layer 12 which is supplied from the supply part 510 and transported by the transport roll 530, by an application part 540. The application part 540 shown in FIG. 4 may be a slot die coater which applies a liquid crystal material held by a tank 541 on the supporting layer 12, using a slot die 542.

In addition, a method for applying the liquid crystal material by the application part 540 is not particularly limited, and a method such as, for example, a spin coating method, a gravure coating method, a spray coating method, and a roll coating method may be applied, in addition to a die coating method.

Subsequently, the liquid crystal material applied on the supporting layer 12 is heated and then dried.

The liquid crystal material applied on the supporting layer 12 is heated by a heating part 550. Thus, the solvent included in the liquid crystal material is evaporated, and the liquid crystal material is dried. In addition, by drying the liquid crystal material by heating, the liquid crystal monomer included in the liquid crystal material is homeotropically aligned.

In addition, in an embodiment, the acrylamide monomer is included in the liquid crystal material, as described above. Thus, even in the case that the liquid crystal material is directly applied on the supporting layer 12, for example, without passing the liquid crystal material through the alignment layer, the liquid crystal monomer may be homeotropically aligned by the action of the acrylamide monomer.

A heating temperature of the liquid crystal material by the heating part 550 may be, for example, 40° or higher and 100° C. or lower. In addition, a heating time of the liquid crystal material by the heating part 550 may be, for example, 30 seconds or more and 3000 seconds or less.

In addition, the heating temperature and the heating time of the liquid crystal material by the heating part 550 are adjusted by the type of liquid crystal monomer included in the liquid crystal material.

Subsequently, the liquid crystal monomer included in the liquid crystal material applied on the supporting layer 12 is polymerized to obtain the liquid crystal layer 11 formed of the polymerizable liquid crystal compound.

The liquid crystal material applied on the supporting layer 12 is irradiated with an active radiation (in this example, ultraviolet rays), by the irradiation part 560. Thus, the liquid crystal monomer included in the liquid crystal material is polymerized and also the liquid crystal monomer is polymerized, thereby fixing the alignment properties of the homeotropically aligned liquid crystal monomer. Due to the facts described above, the liquid crystal layer 11 formed of the polymerizable liquid crystal compound is formed on the supporting layer 12 to obtain a retardation film 10 of an embodiment on which the liquid crystal layer 11 and the supporting layer 12 are laminated.

The wavelength of the ultraviolet rays irradiated (emitted) on the liquid crystal material by the irradiation part 560 may be, for example, 300 nm or more and 400 nm or less, though it varies depending on the type of liquid crystal monomers and the like included in the liquid crystal material.

As described above, even in the case of irradiating (emitting) the liquid crystal material applied on the supporting layer 12 with an active radiation by the irradiation part 560, bonding between the liquid crystal monomer and the acrylamide monomer included in the liquid crystal material does not occur generally. Even in the case of performing various manufacturing methods described above and later, bonding between the liquid crystal monomer and the acrylamide monomer included in the liquid crystal material may not occur.

Irradiation (emission) of the liquid crystal material applied on the supporting layer 12 with an active radiation by the irradiation part 560 according to an disclosure is only for polymerizing the liquid crystal monomer to fix the alignment properties of the homeotropically aligned liquid crystal monomer, and not for a bond between the liquid crystal monomer and the acrylamide monomer.

Thereafter, the obtained retardation film 10 is recovered by the recovery part 520 while winding up the film in a roll shape so that the liquid crystal layer 11 side is an inside.

The retardation film 10 of an embodiment is an example of the display device which displays an image and may be applied to a liquid crystal display device 1.

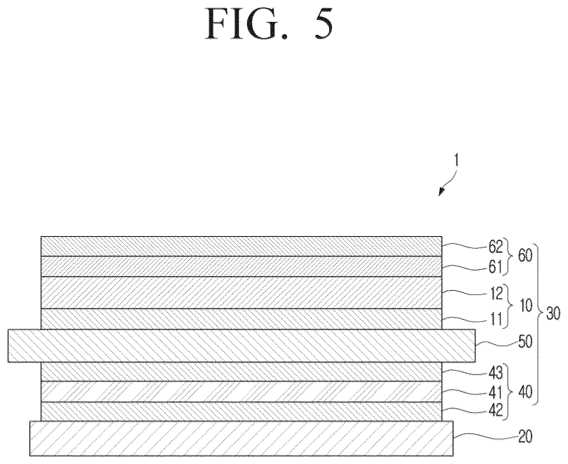

FIG. 5 is a drawing illustrating the liquid crystal display device 1 to which the retardation film 10 of an embodiment is applied and is a drawing showing an example of the cross sectional structure of the liquid crystal display device 1.

The liquid crystal display device 1 displays an image in an in-plane-switching (IPS) manner. The liquid crystal display device 1 has a back light 20 and a liquid crystal panel 30. The back light 20 is provided in the back side of the liquid crystal panel 30, when viewed by a user viewing the liquid crystal display device 1. Further, the liquid crystal display device 1 displays an image by modulating light emitted from the back light 20 by a liquid crystal panel 30.

The back light 20 irradiates (emits) the liquid crystal panel 30 with light. The back light 20 may be an edge type or a direct type. As the back light 20, for example, a cold negative electrode fluorescent lamp, a white light emitting diode (LED), or the like may be used, but an disclosure is not limited thereto.

In the liquid crystal panel 30, a first straight line polarizing plate 40, a liquid crystal cell 50, a retardation film 10, and a second straight line polarizing plate 60 are laminated in this order, from the back light 20 side. In addition, in the liquid crystal panel 30, the retardation film 10 is laminated so that the liquid crystal layer 11 faces the liquid crystal cell 50 and the supporting layer 12 faces the second straight line polarizing plate 60. In an embodiment, the second straight line polarizing plate 60 is an example of the polarization member, and the lamination structure of the retardation film 10 and the second straight line polarizing plate 60 is an example of the optical member.

The first straight line polarizing plate 40 has a polarizer 41 and protective layers 42 and 43 laminated a first surface (surface facing the back light 20) and a second surface (surface facing the liquid crystal cell 50) of the polarizer 41.

In addition, the second straight line polarizing plate 60 has a polarizer 61 and a protective layer 62 which is laminated on the surface opposite to the surface of the polarizer 61 of the retardation film side 10. In addition, the protective layer is not provided on the surface of the retardation film 10 side. In the liquid crystal panel 30 of an embodiment, the retardation film 10 also acts as the protective layer of the polarizer 61.

The polarizer 41 of the first straight line polarizing plate 40 and the polarizer 61 of the second straight line polarizing plate 61 are arranged so that the directions of moisture contraction are orthogonal to each other.

As the polarizer 41 and the polarizer 61, for example, a resin film which is uniaxially extended by absorbing an iodine compound molecule in the film formed of poly-vinyl alcohol (PVA) and the like may be used.

As the protective layers 42 and 43 of the first straight line polarizing plate 40 and the protective layer 62 of the second straight line polarizing plate 60, for example, a film formed of a resin may be used. As the resin, for example, triacetyl cellulose (TAC), polyethylene terephthalate (PET), and the like may be used, but embodiments are not limited thereto.

Regarding the protective layer 43, the retardation in the in-plane direction and the retardation in the thickness direction may be 0 or near 0 for optical compensation of the IPS type liquid crystal display device 1.

The liquid crystal cell 50 is a liquid crystal cell by an IPS method, as described above, and for example, has a cell structure in which a liquid crystal is interposed between two sheets of substrates formed of glass and the like. Further, in the liquid crystal cell 50, power is supplied by a power supply which is not shown, and the liquid crystal rotates horizontally along the in-plane direction of the liquid crystal cell 50, thereby controlling the light transmission state.

As the liquid crystal used in the liquid crystal cell by the IPS method, either a positive type liquid crystal having a dielectric anisotropy in the long axis direction of the molecule or a so-called negative type liquid crystal having a dielectric anisotropy in the short axis direction of the molecule may be applied. In addition, for the structure of an electrode, a striped electric field method, which is referred to as a fringe-field switching (FFS) method, may be applied together with the in-plane-switching (IPS) method, and in a state of no electric field or in a state of being applied to any electric field, a liquid crystal orientation which is aligned to one axis in a cell horizontal direction may be applied.

Herein, in the liquid crystal display device 1 of an embodiment, the second straight line polarizing plate 60 which is an example of the polarization member, the supporting layer 12, and the liquid crystal layer 11 are laminated in this order. Further, the slow axis of the supporting layer 12 in the retardation film 10 and the absorption axis of the polarizer 61 in the second straight line polarizing plate 60 laminated on the retardation film 10 are placed orthogonally.

The liquid crystal display device 1 has the retardation film 10 having the liquid crystal layer 11 and the supporting layer 12, thereby decreasing the light leakage phenomenon in the case that the liquid crystal display device 1 is viewed from an oblique angle in the case of displaying the liquid crystal cell in black. Thus, in the liquid crystal display device 1 having the retardation film 10 of an embodiment, a contrast ratio in the case of being viewed in an oblique direction is improved.

In addition, in the liquid crystal display device 1 shown in FIG. 5, the retardation film 10 is laminated on the liquid crystal cell 50, to the opposite side of the back light 20, but is not limited thereto. The retardation film 10 may be laminated on the liquid crystal cell 50, on the same side of the back light 20.

In addition, in the liquid crystal display device 1 shown in FIG. 5, the retardation film 10 is placed so that the supporting layer 12 is on the side of the second straight polarizing plate 60 (polarizer 61) and the liquid crystal layer 11 is on the side of the liquid crystal cell 60, but is not limited thereto. The retardation film 10 may be placed so that the liquid crystal layer 11 is on the side of the second straight line polarizing plate 60 and the supporting layer 12 is on the side of the liquid crystal cell 50. In addition, the second straight line polarizing plate 60 which is an example of a polarization member, the liquid crystal layer 11, and the supporting layer 12 may be laminated in this order. In this case, the absorption axis of the polarizer 61 and the slow axis of the supporting layer 12 in the second straight line polarizing plate 60 are arranged in parallel.

The retardation film 10 of an embodiment may be applied to an organic EL display device 2 which is an example of a luminescent display device, in addition to the liquid crystal display device 1 described above.

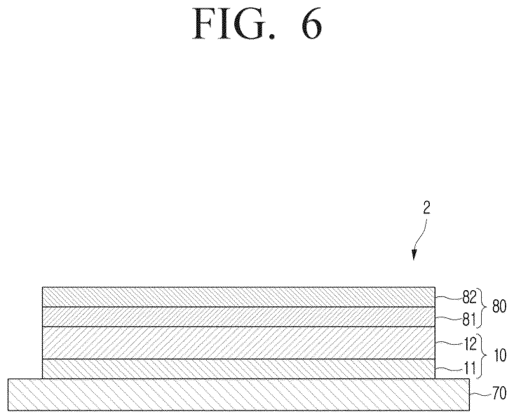

FIG. 6 is a drawing illustrating the organic EL display device 2 to which the retardation film 10 of an embodiment is applied and is a drawing showing an example of the cross sectional structure of the organic EL display device 2.

The organic EL display device 2 has an organic EL display 70 including an organic El light-emitting element, a retardation film 10 laminated on the surface of the organic EL display 70, and a straight line polarizing plate 80 laminated on the surface of the retardation film 10. In addition, in the organic EL display device 2, the retardation film 10 is laminated so that the liquid crystal layer 11 faces the organic EL display and the supporting layer 12 faces the straight line polarizing plate 80. In an embodiment, the straight line polarizing plate 80 is an example of a polarization member, and the lamination structure of the retardation film 10 and the straight line polarizing plate 80 is an example of an optical member. The straight line polarizing plate 80 has a structure in which the polarizer 81 and the protective layer 82 are laminated, like the second straight line polarizing plate 60 in the liquid crystal display device 1 described above.

In the organic EL display device 2, the organic EL display 70, which is supplied by a power supply, emits light and an image is displayed.

In the organic EL display device 2 of an embodiment, an angle formed by the slow axis of the supporting layer 12 in the retardation film 10 and the absorption axis of the polarizer 81 in the straight line polarizing plate 80 laminated on the retardation film 10 may be 40° or more and 50° or less, or 45°.

Since the angle formed by the slow axis of the supporting layer 12 and the absorption axis of the polarizer 81 has the above relationship, the lamination structure of the retardation film 10 and the straight line polarizing plate 80 forms a circular polarizing plate. Thus, external light incident on the organic EL display device 2 is cut by the lamination structure of the retardation film 10 and the straight line polarizing plate 80, and reflection of the external light in the organic EL display device 2 may be suppressed. In addition, the lamination structure of the retardation film 10 and the straight line polarizing plate 80 functions as an anti-reflective film of the organic EL display device 2.

Next, embodiments will be described in more detail using the examples. In addition, an disclosure is not limited to the following examples as long as it does not beyond the gist.

A liquid crystal material including 7 parts by mass of a liquid crystal monomer of the following Formula (I), 13 parts by mass of a liquid crystal monomer of the following Formula (II), 2 parts by mass of an acrylamide monomer, and 0.5 parts by mass of a photopolymerization initiator (product which is a GM Resins B. V. product: Omnirad907) was dissolved in 78 parts by mass of propylene glycol methyl ether acetate, which is a solvent, to prepare a coating solution including the liquid crystal material.

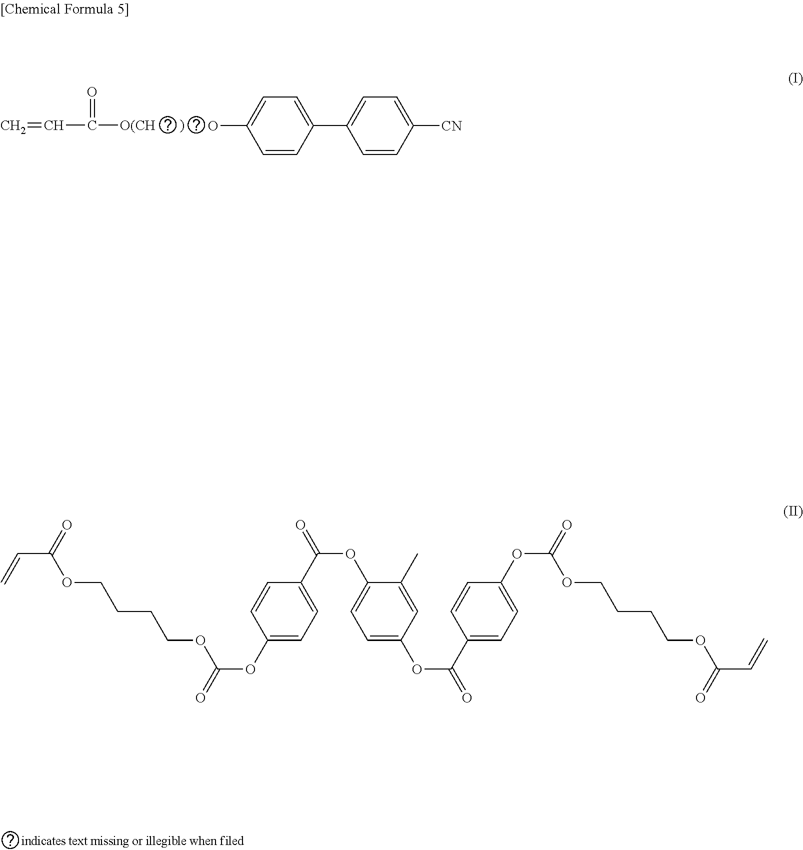

A film formed of COP having a thickness of 30 μm was prepared as a supporting layer 12.

A coating solution including a liquid crystal material was applied on a supporting layer 12 using a slot die coater and then was heat-dried at 80° C. for 3 minutes, thereby homeotropically aligning a liquid crystal monomer. Thereafter, irradiation (emission) with an ultraviolet ray having a wavelength of 365 nm was performed for 30 seconds to polymerize the liquid crystal monomer, a liquid crystal layer 11 having a thickness of 1.2 μm formed of a polymerizable liquid crystal compound was formed, and a retardation film 10 was obtained.

A retardation in the thickness direction Rth(550) of the obtained retardation film 10 was −140 nm.

A process of a related embodiment was performed in the same manner as in Example 1, except that a liquid crystal material including 2 parts by mass of 3-aminopropyltrimethoxysilane instead of the acrylamide monomer as a silane coupling agent was used, thereby obtaining a retardation film 10.

A retardation in the thickness direction Rth(550) of the obtained retardation film 10 was −135 nm.

A process of another related embodiment was performed in the same manner as in Example 1, except that a liquid crystal material including no acrylamide monomer was used, thereby obtaining a retardation film 10.

In the obtained retardation film 10, a liquid crystal monomer was not homeotropically aligned and the retardation in the thickness direction Rth(550) was not able to be measured.

Adhesiveness of the retardation films 10 of Example 1 and Related Example 1 was evaluated by a crosscut test experiment.

First, on the surface of the liquid crystal layer 11 of the retardation film 10, 11 scratches for the background were made, and 100 checkerboard eyes were made, using a cutter knife. When scratching, a cutter knife was used, and the spacing of the scratches was 1 mm.

Thereafter, tape was strongly pressed on the checkerboard eye parts, the end of the tape was peeled off at a 45° angle at once, and the state of the checkerboard eyes was visually observed for evaluation.

As a result of the test, in the retardation film 10 of Example 1, it was confirmed that all of 100 checkerboard eyes shaped films remained, and the adhesiveness between the liquid crystal layer 11 and the supporting layer 12 was high.

In the retardation film 10 of Relate Example 1, it was confirmed that all of 100 checkerboard eyes shaped films were peeled off, and the adhesiveness between the liquid crystal layer 11 and the supporting layer 12 was insufficient.

Reliability of the retardation films 10 of Example 1 and Related Example 1 was evaluated by the following method.

The retardation film 10 was placed in a constant temperature and humidity chamber at 850° C. and 85% and stored for 200 hours. Then, the retardation in the thickness direction Rth of the retardation film 10 before and after the test (before and after placed in the constant temperature and humidity chamber) was compared.

In the retardation film 10 of Example 1, a change amount of the retardation in the thickness direction Rth before and after the test was 2% or less, and there was almost no change. Thus, it was confirmed that the retardation film 10 of Example 1 was difficult to change in quality over time and had improved reliability.

However, in the retardation film 10 of Related Example 1, it was confirmed that the retardation in the thickness direction Rth after the test was reduced by 15% as compared with that before the test, and the reliability was low.

Subsequently, a retardation film 10 having a different content ratio of the material having an amino group in the liquid crystal layer 11 was manufactured, and the evaluation was performed.

A liquid crystal material including 7 parts by mass of a liquid crystal monomer of the following Formula (I), 13 parts by mass of a liquid crystal monomer of the following Formula (II), 0.2 parts by mass of an acrylamide monomer, 0.2 parts by mass of 3-aminopropyltrimethoxysilane as a silane coupling agent having an amino group, and 0.5 parts by mass of a photopolymerization initiator was dissolved in 79.1 parts by mass of propylene glycol methyl ether acetate, which is a solvent, to prepare a coating solution including the liquid crystal material. The content ratio of the material having an amino group was 2 mass %, based on the total amount of the liquid crystal material.

A retardation film 10 was obtained in the same manner as in Example 1, using the prepared coating solution.

A liquid crystal material including 6 parts by mass of a liquid crystal monomer of the following Formula (I), 14 parts by mass of a liquid crystal monomer of the following Formula (II), 1 parts by mass of an acrylamide monomer, 1 parts by mass of 3-aminopropyltrimethoxysilane as a silane coupling agent having an amino group, and 0.5 parts by mass of a photopolymerization initiator was dissolved in 77.5 parts by mass of propylene glycol methyl ether acetate, which is a solvent, to prepare a coating solution including the liquid crystal material. The content ratio of the material having an amino group was 9 mass %, based on the total amount of the liquid crystal material.

A retardation film 10 was obtained in the same manner as in Example 1, using the prepared coating solution.

A liquid crystal material including 5 parts by mass of a liquid crystal monomer of the following Formula (I), 15 parts by mass of a liquid crystal monomer of the following Formula (II), 2 parts by mass of an acrylamide monomer, 1 part by mass of N-2(aminoethyl) 3-aminopropyltrimethoxysilane as a silane coupling agent having an amino group, and 0.5 parts by mass of a photopolymerization initiator was dissolved in 76.5 parts by mass of propylene glycol monomethyl ether, which is a solvent, to prepare a coating solution including the liquid crystal material. The content ratio of a material having an amino group was 13 mass %, based on the total amount of the liquid crystal material.

A retardation film 10 was obtained in the same manner as in Example 1, using the prepared coating solution.

A liquid crystal material including 5 parts by mass of a liquid crystal monomer of the following Formula (I), 15 parts by mass of a liquid crystal monomer of the following Formula (II), 3.5 parts by mass of an acrylamide monomer, 3 part by mass of N-2(aminoethyl) 3-aminopropyltrimethoxysilane as a silane coupling agent having an amino group, and 0.5 parts by mass of a photopolymerization initiator was dissolved in 73.0 parts by mass of propylene glycol monomethyl ether, which is a solvent, to prepare a coating solution including the liquid crystal material. The content ratio of a material having an amino group was 24 mass %, based on the total amount of the liquid crystal material.

A retardation film 10 was obtained in the same manner as in Example 1, using the prepared coating solution.

The retardation films 10 obtained in Examples 2 to 5 were observed, and the alignment state of the liquid crystal monomer in the liquid crystal layer 11 was evaluated. In addition, the retardations in the thickness direction Rth(550) of the retardation films 10 obtained in Examples 2 to Example 5 were measured.

In Table 1, the results of measuring Rth(550) in the thickness direction and visual evaluation of the retardation films obtained in Examples 2 to Example 5 are shown.

TABLE 1

| | Rth(550) | | Visual evaluation |
|---|---|---|---|
| Example 2 | −70 | nm | White turbidity |
| Example 3 | −130 | nm | Transparent |
| Example 4 | −125 | nm | Transparent |
| Example 5 | −80 | nm | Transparent |

Even in the retardation film 10 of any one of Examples 2 to Example 5, the liquid crystal monomer was homeotropically aligned. Therefore, it was confirmed that the liquid crystal monomer is homeotropically aligned in the liquid crystal layer 11, by manufacturing the liquid crystal layer 11 using a liquid crystal material having a content ratio of a material having an amino group of 1 mass % or more and 30 mass % or less.

In addition, upon comparison of the retardation films 10 obtained in Examples 2 to Example 5, in the retardation film 10 of Related Example 2 using the liquid crystal material having a content ratio of the material having an amino group of 2 mass %, the liquid crystal layer 11 had white turbidity, as compared with the retardation films 10 of Examples 3 and 4. In addition, in the retardation film 10 of Example 5 using the liquid crystal material having a content ratio of the material having an amino group of 24 mass %, the alignment of the liquid crystal monomer was lower, and the value of the retardation in the thickness direction Rth was smaller, as compared with the retardation films 10 of Examples 3 and 4. Thus, it was confirmed manufacturing the liquid crystal layer 11 using the liquid crystal material having a content ratio of the material having an amino group of 5 mass % or more and 20 mass % or less has improved retardation.

Subsequently, a retardation film 10 using a supporting layer 12 in which the wavelength dispersion properties of the retardation in the in-plane direction Re_A(λ) were reverse wavelength dispersion properties was manufactured and evaluated.

A supporting layer 12 formed of a film having a thickness of 70 μm was manufactured, using a resin including triacetyl cellulose and diacetyl cellulose at a ratio of 70:30.

A coating solution including a liquid crystal material was manufactured in the same manner as in Example 1.

A coating solution including a liquid crystal material was applied on a supporting layer 12 using a slot die coater and then was heat-dried at 80° C. for 3 minutes, thereby homeotropically aligning a liquid crystal monomer. Thereafter, irradiation (emission) with an ultraviolet ray having a wavelength of 365 nm was performed for 30 seconds to polymerize the liquid crystal monomer, a liquid crystal layer 11 having a thickness of 1.2 μm formed of a polymerizable liquid crystal compound was formed, and a retardation film 10 was obtained.

The retardation film 10 obtained in Example 6 was applied to an IPS type liquid crystal display device 1, and a contrast ratio was evaluated.

First, a second straight line polarizing plate 60 including a polyvinyl alcohol-based polarizer 61 having a thickness of 20 μm and a protective layer 62 formed of triacetyl cellulose having a thickness of 30 μm was prepared. Then, the second straight line polarizing plate 60 was laminated on the side of the support 12 of the retardation film 10 so that the polarizer 61 was on the side of the retardation film 10, and an optical member including the retardation film 10 and the second straight line polarizing plate 60 was obtained. Then, the optical member including the retardation film 10 and the second straight line polarizing plate 60 was attached to the surface of a liquid crystal cell 50 for an IPS type monitor, using an adhesive, so that the retardation film 10 was on the side of a liquid crystal cell 50, then the liquid crystal display device 1 having the lamination structure shown in FIG. 5 was obtained.

Then, an elevation angle (up shot) was changed in a range from −80° to 80°, at an azimuthal angle of 45°, for each of the case that the liquid crystal cell 50 was displayed in white and the case that the liquid crystal cell 50 was displayed in black, and the luminance (e.g., brightness) of the liquid crystal display device 1 was measured. In addition, the elevation angle refers to a tilt angle to the liquid crystal display device 1 (in the direction perpendicular (normal direction) to the surface of the retardation film 10). In addition, an elevation angle of 0° is a normal method of the liquid crystal display device 1. In addition, an elevation angle of 80° is a direction tilted 80° in the direction of an azimuthal angle of 45° from the normal direction of the liquid crystal display device 1, and an elevation angle of −80° is a direction tilted 80° in the opposite direction to an azimuthal angle of 45° (direction of an azimuthal angle of 225°) in the normal direction of the liquid crystal display device 1.

In addition, as Related Example 3, the liquid crystal display device 1 to which the retardation film 10 and the second straight line polarizing plate 60 were not attached was treated in the same manner, and the luminance of the liquid crystal display device 1 was measured for each of the case that the liquid crystal cell 50 was displayed in white and the liquid crystal cell 50 was displayed in black.

Hereinafter, the luminance of the liquid crystal layer 1 in the case of displaying the liquid crystal cell 50 in white was indicated as a white display luminance, and the luminance of the liquid crystal display device 1 in the case of displaying the liquid crystal cell 50 in black was indicated as a black display luminance.

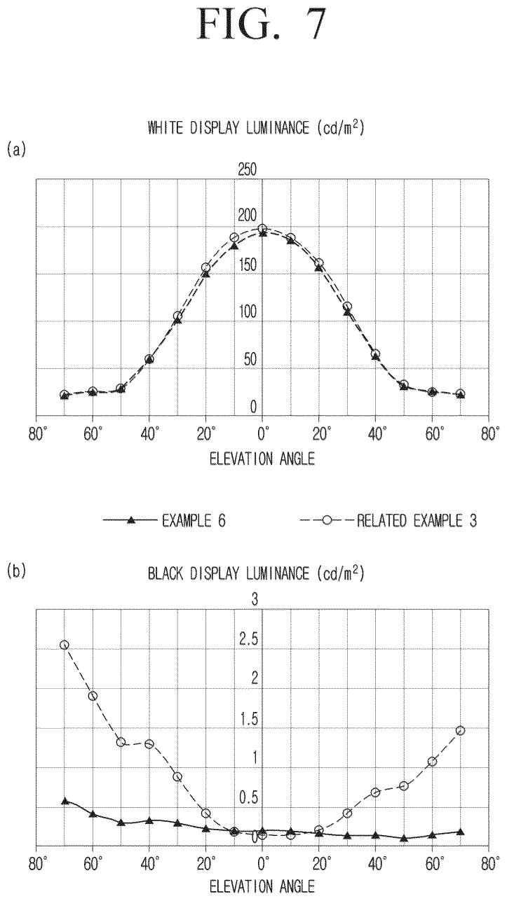

FIG. 7 illustrates graphs showing the results of measuring the luminance of the liquid crystal display device 1. (a) of FIG. 7 shows the results of measuring the white display luminance, and (b) of FIG. 7 shows the results of measuring the black display luminance.

In addition, in Table 1, for Example 6 and Related Example 3, the results of measuring the white display luminance and the black display luminance at an elevation angle of 60°, and a ratio between the white display luminance and the black display luminance (contrast ratio CR) at an elevation angle of 60° are shown. In addition, the contrast ratio CR is a value calculated by (white display luminance)/(black display luminance).

TABLE 2

| | Value at azimuthal angle of 45°/elevation angle 60° | | |
|---|---|---|---|
| | White display | Black display | Contrast |
| | luminance (cd/m2) | luminance (cd/m2) | ratio CR |
| Comparative | 26.7 | 1.50 | 19.2 |
| Example 3 | | | |
| Example 6 | 27.1 | 0.28 | 127 |

As shown in (b) of FIG. 7, in the liquid crystal display device 1 of Related Example 3 having no retardation film 10, as the absolute value of the elevation angle was increased, the black display luminance was increased, and in the case that the liquid crystal display device 1 was viewed from an oblique angle, a light leakage phenomenon of light emitted from the back light 20 occurred. However, in the liquid crystal display device 1 of Example 6 to which the retardation film 10 of an embodiment was applied, an increase in the black display luminance was able to be decreased, even in the case that the absolute value of the elevation angle was increased. Therefore, by applying the retardation film 10 of an embodiment, it was confirmed that the light leakage phenomenon in the case that the liquid crystal display device 1 was viewed from an oblique angle was decreased.

In addition, for the contrast ratio at an elevation angle of 60°, the contrast ratio of Example 6 was increased by 6.6 times as compared with the contrast ratio of Comparative Example 3. Therefore, it was confirmed that the contrast properties of the liquid crystal display device 1 were improved, by applying the retardation film 10 of an embodiment.

The process was performed in the same manner as in Example 3, except that a COP film extended as a supporting layer 12 was used, and the retardation film 10 was obtained.

Then, the obtained retardation film 10 was applied to the liquid crystal display device 1, identically to Example 6, and the contrast ratio was evaluated. For example, identically to Example 6, the second straight line polarizing plate 60 was laminated on the side of the supporting layer 12 of the retardation film 10 so that the polarizer 61 was on the side of the retardation film 10, and an optical member including the retardation film 10 and the second straight line polarizing plate 60 was obtained. Then, the optical member was attached to the surface of a liquid crystal cell 50 for TV using an adhesive so that the retardation film 10 was on the side of the liquid crystal cell 50, and the liquid crystal display device 1 having the lamination structure shown in FIG. 5 was obtained.

Then, the elevation angle was changed in a range from −80° to 80°, at an azimuthal angle of 45°, for each of the case that the liquid crystal cell 50 was displayed in white and the case that the liquid crystal cell 50 was displayed in black, and the luminance of the liquid crystal display device 1 was measured.

In addition, as Related Example 4, the liquid display device 1 to which the retardation film 10 was not attached was treated in the same manner, and the luminance of the liquid crystal display device 1 was measured for each of the case that the liquid crystal cell 50 was displayed in white and the liquid crystal cell 50 was displayed in black.

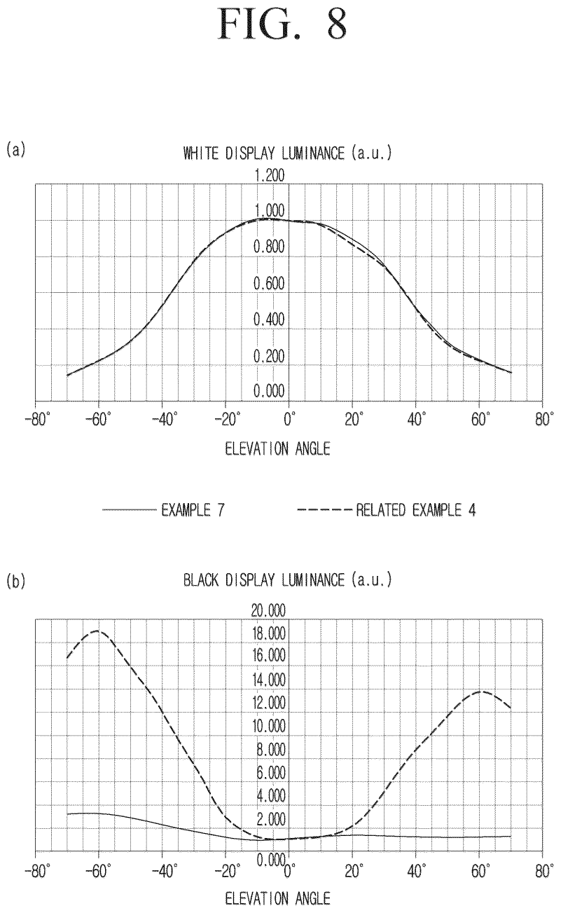

In (a) and (b) of FIG. 8, the results of measuring the luminance of the liquid crystal display device 1 are shown. (a) of FIG. 8 shows the results of measuring the white display luminance, and (b) of FIG. 8 shows the results of measuring the black display luminance. In addition, in (a) and (b) of FIG. 8, standardization was performed so that the luminance at an elevation angle of 0° was 1.

In addition, in Table 3, for Example 7 and Related Example 4, the results of measuring the white display luminance and the black display luminance in the front surface and at an elevation angle of 60°, and the ratio between the white display luminance and the black display luminance (contrast ratio CR) in the front surface and at an elevation angle of 60° are shown.

TABLE 3

| | Value in front surface (azimuthal | | | Value at azimuthal angle of | | |
|---|---|---|---|---|---|---|
| | angle of 45°/elevation angle of 0°) | | | 45°/elevation angle of 60° | | |
| | White | Black | | White | Black | |
| | display | display | | display | display | |
| | luminance | luminance | Contrast | luminance | luminance | Contrast |
| | (cd/m2) | (cd/m2) | ratio CR | (cd/m2) | (cd/m2) | ratio CR |
| Comparative | 405 | 0.46 | 881 | 92 | 10.7 | 8.6 |
| Example 4 | | | | | | |
| Example 7 | 431 | 0.49 | 883 | 96 | 1.0 | 96 |

As shown in (b) of FIG. 8, identically to Comparative Example 3, in the liquid crystal display device 1 of Comparative Example 4 having no retardation film 10, the black display luminance was increased as the absolute value of the elevation angle as increased, and in the case that the liquid crystal display device 1 was viewed from an oblique direction, a light leakage phenomenon of light emitted from the back light 20 occurred. However, in the liquid crystal display device 1 of Example 7 to which the retardation film 10 of an embodiment was applied, an increase in the black display luminance was able to be decreased, even in the case that the absolute value of the elevation angle was increased. Therefore, by applying the retardation film 10 of an embodiment, it was confirmed that the light leakage phenomenon in the case that the liquid crystal display device 1 was viewed from an oblique angle was decreased.

In addition, for the contrast ratio at an elevation angle of 60°, the contrast ratio of Example 7 was increased by 11 times as compared with the contrast ratio of Comparative Example 4. Therefore, it was confirmed that the contrast properties of the liquid crystal display device 1 were improved, by applying the retardation film 10 of an embodiment.

What is claimed is:

1. A liquid crystal material configured to form a polymerizable liquid crystal compound, the liquid crystal material comprising:
a liquid crystal monomer; and
an acrylamide monomer.

2. The liquid crystal material as claimed in claim 1, further comprising a silane coupling agent.

3. The liquid crystal material as claimed in claim 2, wherein the silane coupling agent has an amino group.

4. The liquid crystal material as claimed in claim 1, wherein the liquid crystal monomer comprises at least one of a first liquid crystal monomer having a reaction group at both ends of a molecule and a second liquid crystal monomer having a reaction group at one end and a cyano group at the other end of a molecule.

5. The liquid crystal material as claimed in claim 4, wherein a number of first liquid crystal monomer in the liquid crystal monomer is greater than a number of the second liquid crystal monomer in the liquid crystal monomer.

6. The liquid crystal material as claimed in claim 1 wherein a content of a material having an amino group is greater than or equal to 1 part by mass and less than or equal to 30 parts by mass, based on a total of 100 parts by mass of the liquid crystal material.

7. A laminate comprising:
a supporting layer; and
a liquid crystal layer laminated on the supporting layer, the liquid crystal layer comprising a polymerizable liquid crystal compound that comprises a liquid crystal monomer and an acrylamide monomer.

8. The laminate as claimed in claim 7, wherein the liquid crystal layer is formed by applying a liquid crystal material that comprises a liquid crystal monomer and an acrylamide monomer on the supporting layer and performing polymerization, and
wherein a water contact angle of the supporting layer is greater than or equal to 30° and less than or equal to 60°.

9. The laminate as claimed in claim 7, wherein the liquid crystal layer is a positive C plate, the liquid crystal monomer being homeotropically aligned on the positive C plate,
wherein the liquid crystal layer satisfies:
−50 nm<Rth_C(550)<−150 nm,
where Rth_C(λ) is a retardation for a wavelength λ (nm) of light in a thickness direction of the liquid crystal layer.

10. The laminate as claimed in claim 7, wherein the supporting layer satisfies: nx2≥ny2>nz2,
where refractive indexes in two directions in an in-plane direction of the supporting layer are nx2 and ny2, and a refractive index in a thickness direction of the supporting layer is nz2, and
wherein the liquid crystal layer is a positive C plate, the liquid crystal monomer being crosslinked in a homeotropically aligned state on the positive C plate and is directly laminated on the supporting layer.

11. The laminate as claimed in claim 10, wherein the supporting layer satisfies:
10 nm<Re_A(550)<200 nm,
where a retardation for a wavelength λ (nm) of light in an in-plane direction of the supporting layer is Re_A(λ).

12. The laminate as claimed in claim 10, wherein the supporting layer satisfies:
Re_A(450)<Re_A(550)<Re_A(650),
where a retardation for a wavelength λ (nm) of light in an in-plane direction of the supporting layer is Re_A(λ).

13. The laminate as claimed in claim 10, wherein the supporting layer comprises at least one of diacetyl cellulose, triacetyl cellulose, cellulose acetate butylate, cellulose acetate propionate, cycloolefin, and polycarbonate, as a resin.

14. The laminate as claimed in claim 13, wherein the supporting layer comprises multiple types of resins having different wavelength dispersion properties.

15. The laminate as claimed in claim 10, wherein the supporting layer comprises the resin and particles.
